(19) United States
(12) Patent Application Publication
(10) Pub. No.: US 2025/0137103 A1
(43) Pub. Date: May 1, 2025

(54) COPPER-DIAMOND COMPOSITE, HEAT DISSIPATION MEMBER AND ELECTRONIC DEVICE

(71) Applicant: Denka Company Limited, Chuo-ku, Tokyo (JP)

(72) Inventors: Hyojin Noguchi, Chuo-ku, Tokyo (JP); Noriyoshi Sakai, Chuo-ku, Tokyo (JP); Motoi Nagasawa, Chuo-ku, Tokyo (JP)

(73) Assignee: Denka Company Limited, Chuo-ku, Tokyo (JP)

(21) Appl. No.: 18/681,255

(22) PCT Filed: Aug. 1, 2022
(86) PCT No.: PCT/JP2022/029490

§ 371 Date: Feb. 5, 2024

(30) Foreign Application Priority Data
Aug. 5, 2021 (JP) 2021-128795

(51) Int. Cl. C22C 26/00; H05K 7/20

(52) U.S. Cl. CPC C22C 26/00; H05K 7/20427

(57) ABSTRACT

A copper-diamond composite according to the present invention includes diamond particles that are dispersed in a metal matrix containing copper, in which when a 50% area mean diameter of single-crystal particles of the copper in the metal matrix is represented by A₅₀, A₅₀ is 1 μm or more and 10 μm or less, the 50% area mean diameter being obtained by electron backscatter diffraction.

### TECHNICAL FIELD

The present invention relates to a copper-diamond composite, a heat dissipation member, and an electronic device.

### BACKGROUND ART

Various copper-diamond composites have been developed thus far. As this kind of technique, for example, a technique described in Patent Document 1 is known. Regarding a composite material of a metal matrix and thermally conductive particles, Patent Document 1 describes that an average particle system of highly thermally conductive particles such as diamond particles or SiC particles is 10 to 100 μm or less (for example, paragraph 0060).

### RELATED DOCUMENT

### Patent Document

[Patent Document 1] Pamphlet of International Publication No. WO2016/035796

### SUMMARY OF THE INVENTION

### Technical Problem

However, as a result of investigation by the present inventors, it was found that the composite material described in Patent Document 1 has room for improvement in terms of thermal conductivity.

### Solution to Problem

As a result of further investigation, the present inventors found that the thermal conductivity of the copper-diamond composite can be improved by appropriately controlling cross-sectional areas of single-crystal particles of copper in the copper-diamond composite.

As a result of thorough investigation based on this finding, the present inventors found that the thermal conductivity characteristics can be stably evaluated by using a 50% area mean diameter A₅₀ of single-crystal particles of copper in the metal matrix obtained by electron backscatter diffraction as an index, and also found that the thermal conductivity of the composite can be improved by adjusting the 50% area mean diameter A₅₀ of single-crystal particles of copper to be a predetermined value or less, thereby completing the present invention.

According to one aspect of the present invention, a copper-diamond composite, a heat dissipation member, and an electronic device described below are provided.

1. A copper-diamond composite including:
diamond particles that are dispersed in a metal matrix containing copper, in which
when a 50% area mean diameter of single-crystal particles of the copper in the metal matrix is represented by A₅₀, A₅₀ is 1 μm or more and 10 μm or less, the 50% area mean diameter being obtained from the following procedure including (i) to (iv):

### (Procedure)

(i) a measuring device including a scanning electron microscope and an analyzer is prepared, the analyzer being configured by an electron backscatter diffraction measuring device and software that executes acquisition and analysis of data of an electron backscatter diffraction image obtained by the electron backscatter diffraction measuring device;
(ii) the copper in the metal matrix is set as a measurement target and data of an electron backscatter diffraction image is obtained by electron backscatter diffraction using the measuring device at a step size of 0.2 μm;
(iii) the data of the electron backscatter diffraction image is analyzed by the software, crystal orientations of individual copper particles are identified, regions that are distinguishable for the individual crystal orientations are set as single-crystal particles, and cross-sectional areas of the single-crystal particles are obtained by image analysis using the software; and
(iv) a cumulative curve of the cross-sectional areas of the single-crystal particles is generated, cross-sectional areas of single-crystal particles at a point corresponding to X % are obtained, and when these cross-sectional areas are converted into circles, an X % area mean diameter (A_{X}) of primary particles corresponding to diameters of the circles is obtained.

2. The copper-diamond composite according to 1, in which
when a 10% area mean diameter of single-crystal particles of the copper in the metal matrix obtained from the procedure is represented by A₁₀,

$$( {A}_{50} - {A}_{10} ) / {A}_{50} is 0.3 or more and less than 1. .$$

3. The copper-diamond composite according to 1 or 2, in which
when a 10% area mean diameter of single-crystal particles of the copper in the metal matrix obtained from the procedure is represented by A₁₀ and a 90% area mean diameter of single-crystal particles of the copper in the metal matrix obtained from the procedure is represented by A₉₀,

$$( {A}_{90} - {A}_{10} ) / {A}_{50} is 1. or more and 5. or less .$$

4. The copper-diamond composite according to 3, in which
A₉₀ that is the 90% area mean diameter of the single-crystal particles of the copper is 2 μm or more and 15 μm or less.

5. The copper-diamond composite according to any one of 1 to 4, in which
a thermal conductivity is 600 W/m·K or higher.

6. A heat dissipation member including:
the copper-diamond composite according to any one of 1 to 5; and
a metal film that is joined to at least one face of the copper-diamond composite.

7. An electronic device including:
the heat dissipation member according to 6; and
an electronic component that is provided over the heat dissipation member.

### Advantageous Effects of Invention

According to the present invention, a copper-diamond composite having excellent thermal conductivity, and a heat dissipation member and an electronic device including the same copper-diamond composite are provided.

### BRIEF DESCRIPTION OF THE DRAWINGS

FIG. 1 is a schematic cross-sectional view illustrating an example of a configuration of a copper-diamond composite according to an embodiment.

FIG. 2 is a schematic cross-sectional view illustrating one example of a configuration of a heat dissipation member according to the present embodiment.

FIG. 3 is a diagram illustrating the summary of a measuring device used for electron backscatter diffraction.

FIG. 4 illustrates a SEM image of a copper-diamond composite according to Example 1.

FIG. 5 illustrates an EBSD image of a predetermined region in the SEM image in FIG. 4.

### DESCRIPTION OF EMBODIMENTS

Hereinafter, an embodiment of the present invention will be described using the drawings. In all of the drawings, the same components will be represented by the same reference numerals, and the description thereof will not be repeated. In addition, the diagrams are schematic diagrams, in which a dimensional ratio does not match the actual one.

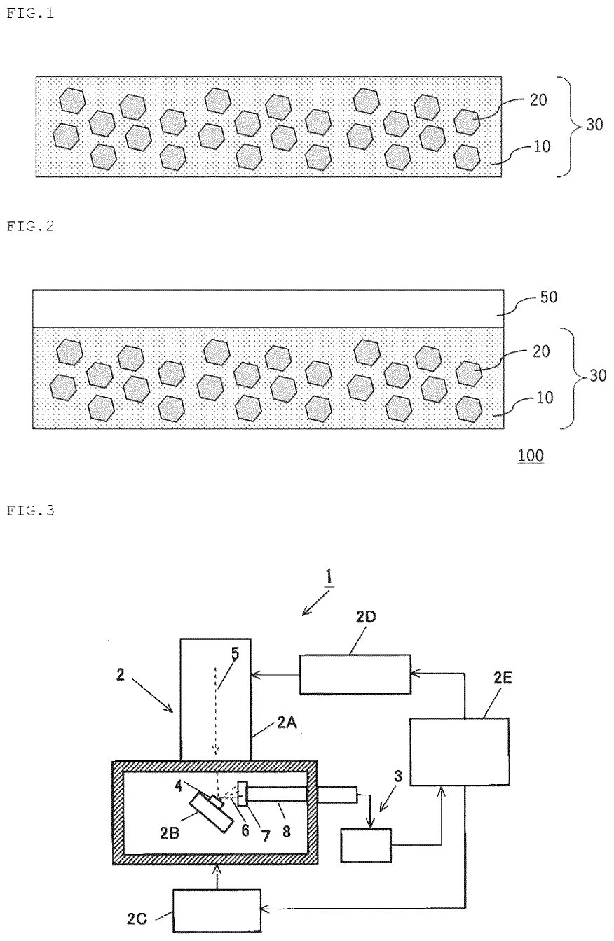

The summary of a copper-diamond composite according to the present embodiment will be described using FIG. 1.

FIG. 1 is a schematic cross-sectional view illustrating an example of a configuration of the copper-diamond composite according to the present embodiment.

The copper-diamond composite 30 according to the present embodiment has a structure in which a plurality of diamond particles 20 are dispersed in a metal matrix 10 containing copper.

In the copper-diamond composite, a 10% area mean diameter of single-crystal particles of copper in the metal matrix 10 is represented by A₁₀, a 50% area mean diameter thereof is represented by A₅₀, and a 90% area mean diameter thereof is represented by A₉₀, the area mean diameters being obtained by the following procedure including (i) to (iv):

### (Procedure)

(i) a measuring device including a scanning electron microscope and an analyzer is prepared, the analyzer being configured by an electron backscatter diffraction measuring device and software that executes acquisition and analysis of data of an electron backscatter diffraction image obtained by the electron backscatter diffraction measuring device;
(ii) the copper in the metal matrix is set as a measurement target and data of an electron backscatter diffraction image is obtained by electron backscatter diffraction (EBSD) using the measuring device at a step size of 0.2 μm;
(iii) the data of the electron backscatter diffraction image is analyzed by the software, crystal orientations of individual copper particles are identified, regions that are distinguishable for the individual crystal orientations are set as single-crystal particles, and cross-sectional areas of the single-crystal particles are obtained by image analysis using the software; and
(iv) a cumulative curve of the cross-sectional areas of the single-crystal particles is generated, cross-sectional areas of single-crystal particles at a point corresponding to X % are obtained, and when these cross-sectional areas are converted into circles, an X % area mean diameter (A_{X}) of primary particles corresponding to diameters of the circles is obtained.

The copper-diamond composite 30 according to the present embodiment is configured to satisfy that A₅₀ of single-crystal particles of copper measured by EBSD described above is 1 μm or more and 10 μm or less. As a result, the thermal conductivity of the copper-diamond composite 30 can be improved.

The upper limit of A₅₀ of single-crystal particles of copper is 10 μm or less, preferably 5 μm or less, and more preferably 3 μm or less.

On the other hand, the lower limit of A₅₀ of single-crystal particles of copper may be, for example, 1 μm or more.

The upper limit of A; of single-crystal particles of copper is, for example, 3 μm or less, preferably 2 μm or less, and more preferably 1 μm or less.

On the other hand, the lower limit of A₁₀ of single-crystal particles of copper may be, for example, 0.1 μm or more.

The upper limit of A₉₀ of single-crystal particles of copper is 15 μm or less, preferably 10 μm or less, and more preferably 7 μm or less. As a result, the thermal conductivity of the copper-diamond composite 30 can be improved.

On the other hand, the lower limit of A₉₀ of single-crystal particles of copper may be, for example, 2 μm or more.

(A₅₀−A₁₀)/A₅₀ may be, for example, 0.3 or more and less than 1.0, preferably 0.4 or more and 0.95 or less, and more preferably 0.5 or more and 0.90 or less. As a result, the thermal conductivity of the copper-diamond composite 30 can be improved.

(A₉₀−A₁₀)/A₅₀ may be, for example, 1.0 or more and 5.0 or less, preferably 1.3 or more and 4.0 or less, and more preferably 1.5 or more and 3.5 or less. As a result, the thermal conductivity of the copper-diamond composite 30 can be improved.

In the present embodiment, for example, by appropriately selecting the kind or mixing amount of each of the components in the copper-diamond composite, a method of manufacturing the copper-diamond composite, and the like, A₁₀, A₅₀, and A₉₀ of single-crystal particles of copper described above can be controlled. In particular, for example, a method of appropriately controlling a particle diameter of copper powder as a raw material of the copper-diamond composite can be used as an element for adjusting A₁₀, A₅₀, and A₉₀ of single-crystal particles of copper to the desired numerical range.

The summary of the configuration of the copper-diamond composite according to the present embodiment will be described in detail.

### (Copper-Diamond Composite)

The copper-diamond composite 30 (hereinafter, also simply referred to as “composite”) includes the metal matrix 10 containing copper and the plurality of diamond particles 20 present in the metal matrix 10.

The diamond particles 20 in the composite are in a state where all the plurality of particles are embedded in the metal matrix 10 but may be in a state where at least a part of one particle or two or more particles is exposed from the surface of the copper-diamond composite 30.

The lower limit of the thermal conductivity of the copper-diamond composite 30 is, for example, 600 W/m·K or higher, preferably 610 W/m·K or higher, and more preferably 630 W/m·K or higher. As a result, the heat dissipation characteristics of the heat dissipation member are enhanced.

On the other hand, the upper limit of the thermal conductivity of the copper-diamond composite 30 is not particularly limited and is, for example, 900 W/m·K or lower, preferably 890 W/m·K or lower, and more preferably 880 W/m·K or lower.

The shape and size of the copper-diamond composite 30 can be appropriately set depending on uses.

Examples of the shape of the copper-diamond composite 30 include a flat shape, a block shape, and a rod shape.

The metal matrix 10 only needs to contain copper or may contain other high thermal conductivity metal other than copper. That is, the metal matrix 10 may be formed of a copper phase and/or a copper alloy phase.

As a main component in the metal matrix 10, copper is preferable from the viewpoint of thermal conductivity or costs.

The lower limit of the content of copper as the main component with respect to 100 mass % of the metal matrix 10 is preferably 50 mass % or more, more preferably 60 mass % or more, still more preferably 70 mass % or more, still more preferably 80 mass % or more, and most preferably 90 mass % or more. As a result, excellent thermal conductivity of the copper and the copper alloy can be used. In addition, in order to ensure brazing property and surface smoothness, the same copper as in the matrix can be used as a surface layer, and another surface coating layer does not need to be formed.

The upper limit of the content of copper as the main component with respect to 100 mass %, of the metal matrix 10 is not particularly limited and may be 100 mass % or less or may be 99 mass % or less.

Examples of the other high thermal conductivity metal include silver, gold, and aluminum. These metals may be used alone or may be used in combination of two or more kinds. When copper and the other high thermal conductivity metal are used in combination, an alloy or a composite material formed of copper and the other high thermal conductivity metal can be used.

In the metal matrix 10, a metal or the like other than the high thermal conductivity metal is allowed within a range where the effect of the present invention does not deteriorate.

In addition, when the copper alloy is used as the metal matrix 10, examples of the copper alloy include CuAg, CuAl, CuSn, CuZr, and CrCu.

The metal matrix 10 is, for example, a sintered compact of metal powder containing copper (and optionally the other high thermal conductivity metal). In the present embodiment, the metal matrix 10 is formed of a sintered compact in which at least a part of the plurality of diamond particles 20 is embedded.

The diamond particles 20 includes at least any one of non-coated diamond particles not including a metal-containing coating layer on the surface or coated diamond particles including a metal-containing coating layer on the surface. From the viewpoint of improving the adhesiveness between diamond and metal particles or obtaining dispersibility, the coated diamond particles are more preferable.

The lower limit of a volume ratio of the diamond particles 20 in the copper-diamond composite 30 is preferably 10 vol % or more, more preferably 20 vol or more, and still more preferably 30 vol % or more. As a result, the thermal conductivity of the copper-diamond composite 30 is enhanced.

On the other hand, the upper limit of the volume ratio of the diamond particles 20 in the copper-diamond composite 30 is, for example, preferably 80 vol % or less, more preferably 70 vol % or less, and still more preferably 65 vol % or less. As a result, in the copper-diamond composite 30, for example, attachment of the copper powder to the periphery of the diamond particles 20 deteriorates. As a result, the remaining of large pores can be suppressed, and a structure having excellent manufacturing stability can be realized.

When the coated diamond particles are used as the diamond particles 20, the metal-containing coating layer in the coated diamond particles may contain molybdenum, tungsten, chromium, zirconium, hafnium, vanadium, niobium, tantalum, and alloys thereof. These metals may be used alone or may be used in combination of two or more kinds. In addition, the metal-containing coating layer is configured to cover at least a part or all of the particle surfaces.

### (Heat Dissipation Member)

FIG. 2 is a schematic cross-sectional view illustrating one example of a configuration of the heat dissipation member according to the present embodiment.

A heat dissipation member 100 according to the present embodiment includes: the copper-diamond composite 30; and a metal film 50 that is joined to at least one face of the copper-diamond composite 30.

The lower limit of the thermal conductivity of the heat dissipation member 100 is, for example, 600 W/m·K or higher, preferably 630 W/m·K or higher, and more preferably 650 W/m·K or higher. As a result, the heat dissipation characteristics of the heat dissipation member are enhanced.

On the other hand, the upper limit of the thermal conductivity of the heat dissipation member 100 is not particularly limited and is, for example, 780 W/m·K or lower, preferably 760 W/m·K or lower, and more preferably 760 W/m·K or lower.

The metal film 50 only needs to be formed on at least one face of the copper-diamond composite 30 and may be formed on each of both faces of the flat copper-diamond composite 30.

The metal film 50 may contain one or two or more selected from the group consisting of copper, silver, gold, aluminum, nickel, zinc, tin, and, magnesium. It is preferable that the metal film 50 includes the same metal as the metal as the main component in the metal matrix 10, and it is more preferable that the metal film 50 includes at least copper or a copper alloy.

The content of copper as the main component with respect to 100 masse of the metal film 50 is preferably 50 mass % or more, more preferably 60 mass % or more, still more preferably 70 mass % or more, still more preferably 80 mass % or more, and most preferably 90 mass % or more.

The upper limit of the content of copper as the main component with respect to 100 mass % of the metal film 50 is not particularly limited and may be 100 mass % or less or may be 99 mass % or less.

The upper limit of the thickness of the metal film 50 is preferably 150 μm or less, more preferably 120 μm or less, and still more preferably 100 μm or less. As a result, the thermal conductivity of the heat dissipation member is enhanced.

On the other hand, the lower limit of the thickness of the metal film 50 is preferably 10 μm or more, more preferably 15 μm or more, and still more preferably 20 μm or more. As a result, the adhesion strength with the composite or the durability of the metal film 50 itself is enhanced.

The metal film 50 is obtained, for example, using a sputtering method or a plating method.

An electronic device according to the present embodiment includes the above-described heat dissipation member and an electronic component that is provided over the heat dissipation member.

Examples of the electronic component include a semiconductor element. Specific examples of the semiconductor element include a power semiconductor, an image display element, a microprocessor unit, and a laser diode.

The heat dissipation member is used as a heat sink, a heat spreader, or the like. The heat sink dissipates heat generated during an operation of the semiconductor element to an external space, and the heat spreader spreads heat generated from the semiconductor element to other members.

The electronic component may be provided in the heat dissipation member directly or indirectly through a ceramic substrate or the like.

An example of a method of manufacturing the copper-diamond composite according to the present embodiment will be described.

The example of the method of manufacturing the copper-diamond composite includes a raw material mixing step and a sintering step.

In the raw material mixing step, metal powder including copper such as copper powder and diamond particles are mixed to obtain a mixture.

To the mixing of the raw material powders, various methods such as a dry process or a wet process can be applied, and a dry mixing method may also be used.

In the firing step, the mixture of the metal powder and the diamond particles is fired to obtain a composite sintered compact (copper-diamond composite) of copper and the diamond particles.

The firing temperature can be appropriately selected depending on metal species in the metal powder. The firing temperature of the copper powder is preferably 800° C. or higher and 1100° C. or lower and more preferably 850° C. or higher and 1000° C. or lower. By adjusting the firing temperature to be 800° C. or higher, the copper-diamond composite is densified to obtain a desired thermal conductivity. By adjusting the firing temperature to be 1100° C. or lower, deterioration of the interface of the diamond particles caused by graphitization can be suppressed, and a decrease in the thermal conductivity of diamond itself can be prevented.

The firing time is not particularly limited and is preferably 5 minutes or longer and 3 hours or shorter and more preferably 10 minutes or longer and 2 hours or shorter. By adjusting the firing time to be 5 minutes or longer, the copper-diamond composite is densified to obtain a desired thermal conductivity. By adjusting the firing time to be 3 hours or shorter, the formation of a carbide between diamond in the coated diamond particles and the metal with which the surfaces are coated or an increase in film thickness can be suppressed, and a decrease in thermal conductivity caused by phonon scattering or the occurrence of cracks caused by a difference in linear expansion coefficient can be suppressed. In addition, the productivity of the composite is improved.

In the firing step, a pressureless sintering method or a pressure sintering method may be used, and a pressure sintering method is preferable to obtain a dense composite.

Examples of the pressure sintering method include hot press sintering, spark plasma sintering (SPS), and hot isotropic pressure sintering (HIP). In hot press sintering or SPS sintering, the pressure is preferably 10 MPa or higher and more preferably 30 MPa or higher. On the other hand, in hot press sintering or SPS sintering, the pressure is preferably 100 MPa or lower. By adjusting the pressure to be 10 MPa or higher, the copper-diamond composite is densified to obtain a desired thermal conductivity. By adjusting the pressure to be 100 MPa or lower, the fracture of diamond can be prevented, an increase in diamond interface or a decrease in adhesiveness between a diamond fracture surface and metal can be prevented, and a decrease in the thermal conductivity of diamond itself can be prevented.

In addition, one example of a method of manufacturing the heat dissipation member includes a film forming step of forming a metal film on the composite obtained as described above.

In the film forming step, the metal film 50 is formed on at least a part of the surface of the copper-diamond composite 30.

As a method of forming the metal film, a general method such as a sputtering method, a plating method, or a pressure co-firing method using copper foil may be adopted. However, a sputtering method may be used to reduce the film thickness.

In addition, at least a part of the surface of the metal film may be ground and polished. As a result, the surface smoothness of the metal film after the film forming step can be improved.

In addition, optionally, a smoothing step may be performed after the firing step. In the smoothing step, at least a part of the surface of the composite sintered compact is ground and polished.

In addition, an annealing step may be added and performed between the firing step and the smoothing step.

In addition, a step of performing processing such as shaping or perforating on the copper-diamond composite may be performed before the film forming step.

Hereinbefore, the embodiment of the present invention has been described. However, the embodiment is merely an example of the present invention, and various configurations other than the above-described configurations can be adopted. In addition, the present invention is not limited to the above-described embodiments, and modifications, improvements, and the like within a range where the object of the present invention can be achieved are included in the present invention.

### EXAMPLES

Hereinafter, the present invention will be described in detail with reference to Examples. However, the present invention is not limited to the description of these Examples.

### <Preparation of Composite>

### Example 1

Copper powder A (average particle diameter D₅₀: 0.45 μm) and diamond particles (coated with Mo) were weighed at 50 vol %:50 vol %, and the weighed powders were uniformly mixed using a V-shape mixer to obtain a mixture (raw material mixing step).

Next, using a SPS firing device, the obtained mixture was filled in a mold and was heated and sintered in a vacuum atmosphere at 900° C. for 10 minutes under a pressure condition of 30 MPa at a temperature increase rate of 50° C./min. As a result, a disk-shaped composite sintered compact (copper-diamond composite) where a plurality of diamond particles were dispersed in the copper matrix was obtained (sintering step).

A particle size distribution (shape distribution/particle diameter distribution) of the diamond particles as a raw material was measured using an image particle size distribution analyzer (for example, Morphologi 4, manufactured by Malvern Panalytical Ltd.).

A particle diameter D₅₀ corresponding to a cumulative value of 50% in the volume particle size distribution of particle diameter of the diamond particles was obtained.

The particle diameter was defined as follows.

Particle diameter: the maximum length between two points on the contour of a particle image

The content of the diamond particles in the copper-diamond composite was 45 vol %.

When the thermal conductivity of the copper-diamond composite was measured using a laser flash method, the result was 650 W/m·K. The measurement using the laser flash method was performed at room temperature according to JIS H 7801 after coating the sample surface with carbon.

### [10%, 50%, 90% Area Mean Diameters of Single-Crystal Particles of Copper]

A 10% area mean diameter A₁₀, a 50% area mean diameter A₅₀, and a 90% area mean diameter A₉₀ of single-crystal particles of copper in the metal matrix (copper matrix) were obtained by the following procedure including (i) to (iv).
Procedure (i) A measuring device including a scanning electron microscope and an analyzer was prepared, the analyzer being configured by an electron backscatter diffraction measuring device and software that executes acquisition and analysis of data of an electron backscatter diffraction image obtained by the electron backscatter diffraction measuring device.

FIG. 3 is a schematic diagram illustrating a configuration of a measuring device 1 used for electron backscatter diffraction (hereinafter, also referred to as “EBSD”).

As illustrated in FIG. 3, the measuring device 1 used for EBSD was configured by a device where an electron backscatter diffraction measuring device 3 was added to a scanning electron microscope 2. Specifically, the device where the electron backscatter diffraction measuring device (OIM device, manufactured by EDAX-TSL) was added to the scanning electron microscope (FE-SEM, JSM-7000F type manufactured by JEOL Ltd.) was used.

The scanning electron microscope 2 was configured by a lens barrel unit 2A, a stage unit 2B on which a sample 4 is placed, a stage control unit 2C, an electron beam scanning unit 2D, a control computer 2E, and the like. The electron backscatter diffraction measuring device 3 was configured by a fluorescent screen 7 that detects backscattered electrons 6 generated by irradiation of the sample 4 with an electron beam 5, a camera 8 that obtains a fluorescence image of the fluorescent screen 7, software that executes acquisition and analysis of data of an electron backscatter diffraction image (not illustrated), and the like.
Procedure (ii) the copper in the metal matrix was set as a measurement target and data of an electron backscatter diffraction image was obtained by electron backscatter diffraction (EBSD) using the measuring device 1 at a step size of 0.2 μm.

Measurement conditions of crystal orientations obtained by EBSD are as follows.
Acceleration voltage: 20 kV
Working distance: 21 mm
Sample tilt angle: 70°
Measurement region: 16 μm×27 μm
Step size: 0.1 μm
Number of data points: about 400,000 points
Procedure (iii) the data of the electron backscatter diffraction image was analyzed by the software, crystal orientations of individual copper particles were identified, regions that are distinguishable for the individual crystal orientations were set as single-crystal particles, and cross-sectional areas of the single-crystal particles were obtained by image analysis using the software.

Specifically, the copper-diamond composite was irradiated with an electron beam to cause scattering corresponding to a crystal structure and a crystal orientation, and the shape of the scattering pattern was analyzed by software (OIM 7.3, manufactured by TSL solutions LLC) to identify crystal orientations of the individual phosphor particles.

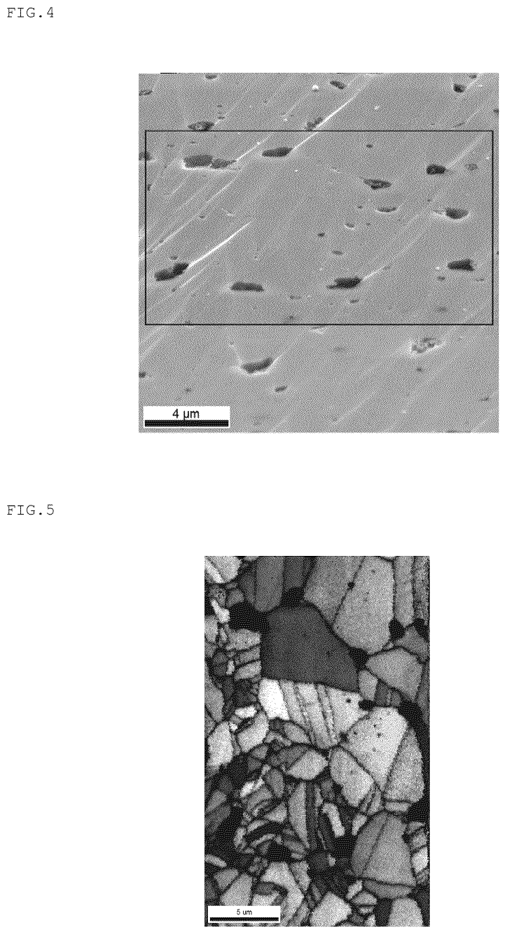

In the image analysis, the EBSD image of FIG. 5 was obtained from the copper-diamond composite illustrated in a scanning electron microscope image of FIG. 4 (SEM image, electron acceleration voltage: 10 kV, magnification: 97-fold). FIG. 5 illustrates a region in a box of FIG. 4.

In FIG. 5, portions other than the black background are the primary particles, and lines in the respective contours represent boundaries between the primary particles having different orientations. As the number of primary particles increases, the statistical analysis accuracy is improved. When the number of primary particles is 3000 or more, sufficient data can be obtained for analysis.
Procedure (iv) a cumulative curve of the cross-sectional areas of the single-crystal particles was generated, cross-sectional areas of single-crystal particles at a point corresponding to X % were obtained, and when these cross-sectional areas were converted into circles, an X % area mean diameter (A_{X}) of primary particles corresponding to diameters of the circles was obtained from the following Expressions (1), (2), and (3).

50% area mean diameter of primary particles=2×(A₅₀/π)^{1/2} (1)

In the expression, A₅₀ is the area of the primary particle at the point where the cumulative curve of the areas of individual primary particles is 50%.

10% area mean diameter of primary particles=2×(A₁₀/π)^{1/2} (2)

In the expression, A₁₀ is the area of the primary particle at the point where the cumulative curve of the areas of individual primary particles is 10%.

90% area mean diameter of primary particles=2×(A₁₀/π)^{1/2} (3)

In the expression, A₉₀ is the area of the primary particle at the point where the cumulative curve of the areas of individual primary particles is 90%.

### Comparative Example 1

A copper-diamond composite was obtained using the same method as that of Example 1, except that copper powder B (average particle diameter D₅₀: 17.3 μm) was used instead of the copper powder A. The same evaluation as that of Example 1 was performed on the obtained composite.

In Example 1, in single-crystal particles of copper, A₁₀ was 0.3 μm, A₅₀ was 1.48 μm, A₉₀ was 4.4 μm, (A₅₀−A₁₀)/A₅₀ was 0.80, and (A₉₀−A₁₀)/A₅₀ was 2.77, and the thermal conductivity of the composite was 650 W/m·K.

In Comparative Example 1, A₅₀ of single-crystal particle of copper was more than 20 μm, and the thermal conductivity of the composite was 544 W/m·K.

The above measurement results show that, in the copper-diamond composite according to Example 1, the thermal conductivity was improved as compared to Comparative Example 1. By using the composite according to Example, a heat dissipation member having excellent thermal conductivity can be provided.

The present application claims priority based on Japanese Patent Application No. 2021-128795, filed on Aug. 5, 2021, the entire content of which is incorporated herein by reference.

### REFERENCE SIGNS LIST

1: measuring device used for EBSD
2: scanning electron microscope
2A: lens barrel unit
B: stage unit
2C: stage control unit
2D: electron beam scanning unit
2E: control computer
3: electron backscatter diffraction measuring device
4: sample
5: electron beam
6: backscattered electron
7: fluorescent screen
8: camera
10: metal matrix
20: diamond particle
30: copper-diamond composite
50: metal film
100: heat dissipation member

1. A copper-diamond composite comprising:
diamond particles that are dispersed in a metal matrix containing copper, wherein
when a 50% area mean diameter of single-crystal particles of the copper in the metal matrix is represented by A₅₀, A₅₀ is 1 μm or more and 10 μm or less, the 50% area mean diameter being obtained from the following procedure including (i) to (iv):
(Procedure)
(i) a measuring device comprising a scanning electron microscope and an analyzer is prepared, the analyzer being configured by an electron backscatter diffraction measuring device and software that executes acquisition and analysis of data of an electron backscatter diffraction image obtained by the electron backscatter diffraction measuring device;
(ii) the copper in the metal matrix is set as a measurement target and data of an electron backscatter diffraction image is obtained by electron backscatter diffraction using the measuring device at a step size of 0.2 μm;
(iii) the data of the electron backscatter diffraction image is analyzed by the software, crystal orientations of individual copper particles are identified, regions that are distinguishable for the individual crystal orientations are set as single-crystal particles, and cross-sectional areas of the single-crystal particles are obtained by image analysis using the software; and
(iv) a cumulative curve of the cross-sectional areas of the single-crystal particles is generated, cross-sectional areas of single-crystal particles at a point corresponding to X % are obtained, and when these cross-sectional areas are converted into circles, an X % area mean diameter (A_{X}) of primary particles corresponding to diameters of the circles is obtained.

2. The copper-diamond composite according to claim 1, wherein
when a 10% area mean diameter of single-crystal particles of the copper in the metal matrix obtained from the procedure is represented by A₁₀,
$$( {A}_{50} - {A}_{10} ) / {A}_{50} is 0.3 or more and less than 1. .$$

3. The copper-diamond composite according to claim 1, wherein
when a 10% area mean diameter of single-crystal particles of the copper in the metal matrix obtained from the procedure is represented by A₁₀, and a 90% area mean diameter of single-crystal particles of the copper in the metal matrix obtained from the procedure is represented by A₉₀,
$$( {A}_{90} - {A}_{10} ) / {A}_{50} is 1. or more and 5. or less .$$

4. The copper-diamond composite according to claim 3, wherein
A₉₀ that is the 90% area mean diameter of the single-crystal particles of the copper is 2 μm or more and 15 μm or less.

5. The copper-diamond composite according to claim 1, wherein
a thermal conductivity is 600 W/m·K or higher.

6. A heat dissipation member comprising:
the copper-diamond composite according to claim 1; and
a metal film that is joined to at least one face of the copper-diamond composite.

7. An electronic device comprising:
the heat dissipation member according to claim 6; and
an electronic component that is provided over the heat dissipation member.
